(19) United States
(12) Patent Application Publication
(10) Pub. No.: US 2008/0079095 A1
(43) Pub. Date: Apr. 3, 2008

(54) METAL OXIDE SEMICONDUCTOR DEVICE AND METHOD FOR MANUFACTURING THE SAME

(75) Inventors: Haohua YE, Shanghai (CN); Hok Min HO, Shanghai (CN); Yu Ll, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 11/860,492

(22) Filed: Sep. 24, 2007

(30) Foreign Application Priority Data
Sep. 30, 2006 (CN) 200610116846.7

(51) Int. Cl. H01L 29/78; H01L 21/336

(52) U.S. Cl. 257/408; 438/305; 257/E21.435; 257/E29.266

(57) ABSTRACT

A Metal Oxide Semiconductor device includes a semiconductor substrate; a gate electrode formed on the surface of the substrate, having an offset spacer on each side; source/drain electrodes in the substrate having lightly doped regions respectively; metal silicide located on the gate electrode and the source/drain electrodes; and first impurity ions and second impurity ions in the lightly doped regions. A method for manufacturing a Metal Oxide Semiconductor device includes forming a gate electrode on a semiconductor substrate; implanting first impurity ions and second impurity ions to form lightly doped regions; depositing a dielectric layer and etching the dielectric layer to form offset spacers; implanting the first impurity ions to form the source/drain electrodes; forming metal silicide on the surfaces of the gate electrode and the source/drain regions. This invention can effectively prevent metal nickel diffusion into the lightly doped regions.

### FIELD OF THE INVENTION

The present invention relates to the field of semiconductor manufacturing technology, and particularly to a Metal Oxide Semiconductor (MOS) device and a method for manufacturing the same.

### BACKGROUND OF THE INVENTION

With rapid development of the semiconductor manufacturing technology, in order to achieve faster operation speed, larger data storage capacity and more functions of semiconductor devices, semiconductor wafers have been developed towards higher component density and higher integrity. As the ate electrode feature size of a device has entered the stage of deep-sub micron, gate electrode width is becoming thinner and thinner and gate electrode length becomes much shorter than before. To obviate short channel effect, a lightly doped drain (LDD) structure is employed at present, which is generally referred to as extension doping. FIG. 1 is a cross-section schematic diagram illustrating the LDD structure of a MOS device. As shown in FIG. 1, impurity ions 170 are implanted to form lightly doped regions 121 and 131 after a gate electrode 140 is formed on a semiconductor substrate 100. For a NMOS device, the impurity ions 170 of n-type are phosphorus (P⁺) ions or arsenic (As⁺) ions.

Then an offset spacer is formed on each side of the gate electrode, and a source electrode 120 and a drain electrode 130 are formed employing the self-aligned technology. In an ultra high-speed large scale MOS integrated circuit, in order to reduce sheet resistance and parasitic resistance of the source/drain electrodes and the gate electrode, a reaction resultant, i.e. metal silicide, produced by the reaction of metal and semiconductor such as silicon (Si), is formed on the source/drain regions and the gate electrode composed of polycrystalline silicon on the semiconductor substrate to get favorable low-resistance contact. FIG. 2 is a schematic diagram illustrating position of the metal silicide in a transistor. As shown in FIG. 2, metal silicide layers 151, 152 and 153 are respectively arranged on the source electrode 120, the drain electrode 130 and the gate electrode 140, used for reducing sheets resistance between metal contacts and the underlying structures, as well as contact resistances between contact holes of an upper interconnection structure and each electrode of the transistor.

From 0.13 um technical node to 90 nm technical node, the CMOS technology mainly employs cobalt silicide (CoSi) as contact layers. After the technology node advances forward, device sizes are becoming smaller and smaller. The resistance of CoSi with narrow line width will become too large to be accepted, while the resistance of nickel silicide varies little with line width, so the adoption of nickel silicide is inevitable.

Nickel (Ni) is used to substitute for Co to form nickel silicide (NiSi) acting as contact layers beyond 90 nm technology node. Especially for 65 nm node and beyond, since Ni has no line width effect, and it has lower silicon consumption, lower thermal budget and lower contact resistance, Ni is used for substituting for Co beyond 65 nm technology node.

However, NiSi is not as stable as CoSi at high temperatures, and Ni₂Si with high resistance will be formed when the temperature is higher, so the annealing temperature of Ni must be controlled to be in the range of 350° C. to 450° C. Since the diffusion coefficient of Ni in silicon is relatively large, when the temperature is higher than 450° C., the silicidation reaction of Ni will be diffusely carried out in silicon. Taking Ni as an example of the metal of the metal silicide in FIG. 3, as shown in FIG. 3, for a NMOS device, since impurity ions will generate relatively strong pressure stress in the lightly doped regions 121 and 131 of the source electrode 120 and the drain electrode 130 after the n-type impurity is implanted, and such stress will pull nickel atoms to the narrow lightly doped regions 121 and 131, which will lead the nickel atoms to diffuse towards the above-mentioned regions, and thereby metal silicide 160 will be formed in these regions. Beyond 65 nm technology node, the source/drain regions of the MOS devices are very dense, and the existence of the metal silicide 160 will shorten the channel, so the short channel effect will be exacerbated and the probability of generating leakage current will be increased.

U.S. Pat. No. 6,180,469 discloses a method for forming metal silicide layers on the surfaces of the gate electrode and the source/drain regions. According to this method, after nickel layers are selectively formed on the surfaces of the gate electrode and the source/drain regions by adopting chemical plating, nitrogen ions (N⁺) are implanted into the nickel layers, forming barrier layers dividing the Ni layers into lower portions and upper portions to reduce the Ni diffusion into silicon. But there is no doubt that the difficulty in controlling process of selectively forming silicide employing ion implantation layer division are relatively great, and the risk of Ni transversely diffusing into the lightly doped regions still exists. So, during the process of forming contact layers of source/drain electrode metal silicide of a NMOS device, effectively preventing metal transverse diffusion is still one of the huge challenges for the 65 nm technology.

### SUMMARY OF THE INVENTION

An object of the present invention is to provide a Metal Oxide (MOS) Semiconductor device and a method for manufacturing the device, and for NMOS devices, the method can effectively prevent nickel from diffusing to lightly doped regions.

To achieve the above object, the present invention provides an MOS device, which includes:

a semiconductor substrate;

a gate electrode formed on the surface of the substrate, with offset spacers on both sides of the gate electrode;

a source electrode and a drain electrode located in the substrate, the source electrode and the drain electrode respectively having a lightly doped region;

metal silicide located on the surfaces of the gate electrode and source/drain regions; wherein

first impurity ions and second impurity ions are included in the lightly doped regions.

The first impurity is one of phosphorus, arsenic and antimony.

The second impurity is one of carbon, nitrogen and fluorine.

The substrate is a P-type substrate.

The metal silicide is SiNi.

And accordingly, the present invention provides a method for manufacturing a Metal Oxide Semiconductor device, which includes:

forming a gate electrode on a semiconductor substrate;

implanting first impurity ions and second impurity ions into the parts of the substrate under each side of the gate electrode to form lightly doped regions;

depositing a dielectric layer and etching the dielectric layer to form offset spacers;

implanting the first impurity ions to form a source electrode and a drain electrode;

forming metal silicide on the surfaces of the gate electrode, the source electrode and the drain electrode.

The substrate is a p-type substrate.

The first impurity is one of phosphorus, arsenic and antimony.

The second impurity is one of carbon, nitrogen or fluorine.

The metal silicide is SiNi.

The second impurity ions are implanted at an implantation energy of about 1 KeV to about 6 KeV.

The second impurity ions are implanted at a dosage of about 1E14 ions/cm² to about 1E15 ions/cm².

Compared with prior art, the present invention has the following advantages:

According to the present method for manufacturing a semiconductor device, in addition to n-type impurity ions being implanted into a substrate, another impurity ions, such as carbon ions, are implanted into the substrate during the process of forming lightly doped regions of NMOS devices. After the device being annealed, the n-type impurity ions and the carbon ions disperse evenly in the lightly doped regions. The atom-bond interaction of the carbon ions and the n-type impurity ions can obviate pressure stress generated by the n-type impurity ions in the substrate. In this way, in subsequent processes of forming metal silicide, when metal Ni deposited on the surface of the source/drain electrodes undergoes silicidation reaction, Si atoms will lose outside forces which make the Si atoms to move towards the channel across the lightly doped regions. Thus metal Ni is prevented from diffusing towards the channel due to the implantation of carbon ions, and the possibility of forming metal silicide in the lightly doped regions near the channel is obviated, and therefore the chance of generating leakage currents is lowered. Accordingly the performance of the NMOS device is improved.

### BRIEF DESCRIPTION OF THE DRAWINGS

The above-mentioned object, characteristics and advantages will be clearer through the detailed description of the preferred embodiments in accordance with the present invention taken in conjunction with the accompanying drawings. The same components in the drawings are denoted with the same reference signs. The drawings, not precisely plotted according to the scale, are used to show the major ideas of the present invention. In the accompanying drawings, the thicknesses of layers and regions are scaled up for the sake of clarity.

FIG. 1 is a cross-section schematic diagram illustrating a lightly doped drain structure of a MOS device.

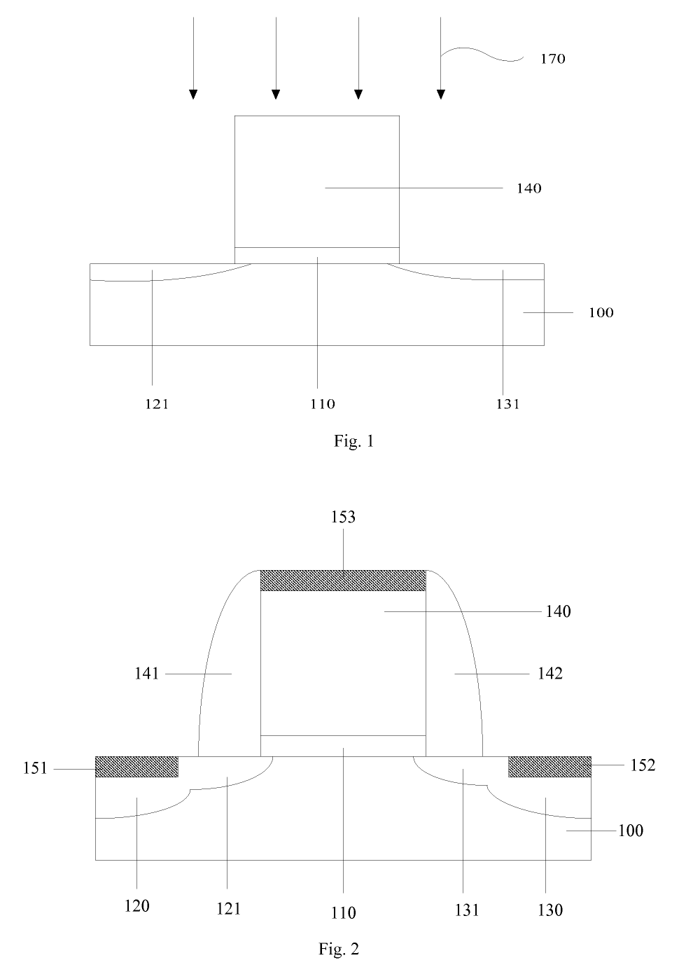

FIG. 2 is a schematic diagram illustrating position of a metal silicide layer in a transistor.

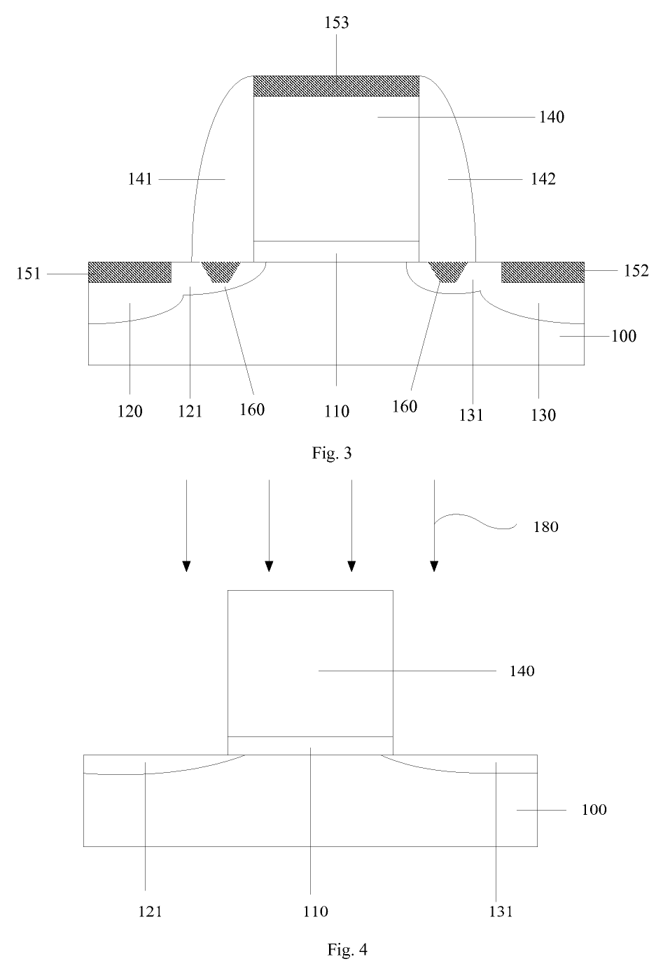

FIG. 3 is a cross-section schematic diagram illustrating a NMOS device with metal transverse diffusion phenomenon.

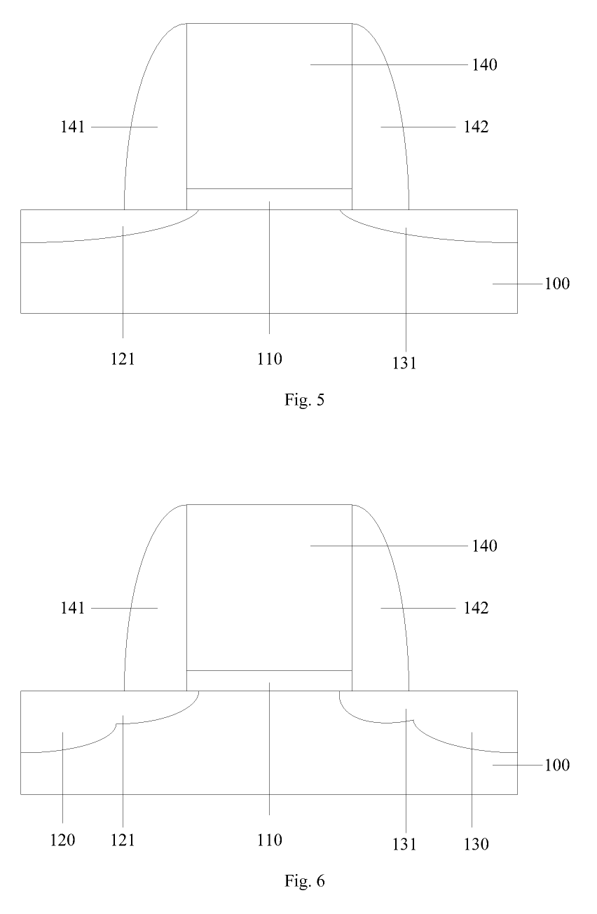

FIGS. 4-7 are cross-section schematic diagrams illustrating a method for manufacturing the device according to an embodiment of the present invention.

### DETAILED DESCRIPTION OF THE EMBODIMENTS

Specific embodiments of the present invention will be described in detail with reference to the accompanying drawings, in order to make the above object, characteristics and advantages of the present invention more obvious and easier to be understood.

Numerous specific details are set forth in the following description in order to provide a better understanding of the present invention. However, the present invention can be implemented in many manners other than those specifically set forth herein, and those skilled in the art can make similar popularization without departing the spirit of the present invention. So the present invention is not limited by the specific implementations disclosed hereinafter.

The MOS device and the method for manufacturing the device according to an embodiment of the present invention are especially suitable for NMOS devices whose feature size is 65 nm or below 65 nm as well as the manufacture thereof.

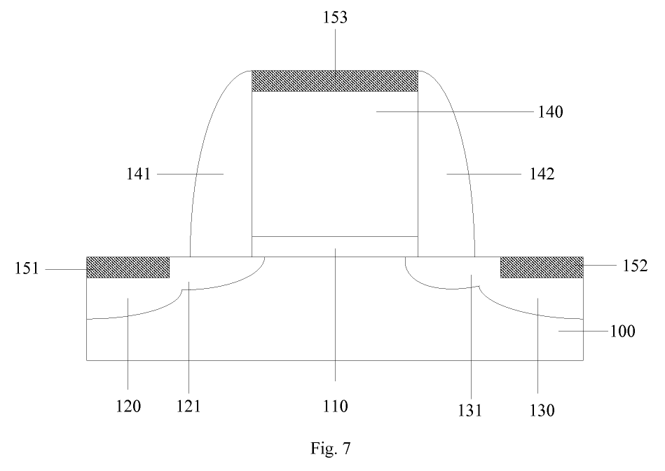

FIGS. 4-7 are cross-section schematic diagrams illustrating the method for manufacturing the device according to the embodiment of the present invention. Here the schematic diagrams just show an example, but are not intended to excessively limit the scope of the present invention. As shown in FIG. 4, a semiconductor substrate 100 is provided. The substrate 100 can be an integral semiconductor substrate, such as monocrystalline, polycrystalline or non-crystalline silicon or SiGe, or a mixed semiconductor structure (such as SiC, GaAs, GaP, InSb, InP, InAs, GaAs or GaSb). It can also be a substrate of semiconductor-on-insulator structure, for example, Silicon on Insulator (SOI). Or it can also include alloy semiconductors (such as GaAsP, AlInAs, AlGaAs, GaInAs, GaInP, GaInAsP) or combinations thereof. Although several examples of the material that can be used to form the substrate 100 are described herein, any material which can be used as a semiconductor substrate falls within the spirit and the scope of the present invention.

A gate electrode layer 110 is formed on the surface of the substrate 100. Proper materials, such as SiO₂ or SiNO, can be selected and used for the gate dielectric layer 110. A gate dielectric layer 110 beyond the 65 nm technology node needs to have high reliability and low leakage current, so, preferably, the materials for the gate dielectric layer are those with high dielectric constant (high k). The dielectric constant of the high k material in the present description is greater than 10. The high k materials which can be used to form the gate dielectric layer include HfO₂, HfSiO₄, HfSiNO, La₂O₃, ZrO₂, ZrSiO₄, TiO₂, Ta₂O₅, BaSrTiO₃, BaTiO₃, SrTiO₃, Al₂O₃ and so on. Especially preferred are HfO₂, ZrO₂, Al₂O₃, HfO₂—Al₂O₃ alloy or any combination thereof. Although a few examples of the material which can be used to form the gate dielectric layer 110 are described here, this layer also can be formed by other materials that can reduce the gate leakage current. The method of growing the gate dielectric layer 110 can be any conventional vacuum coating technology, such as Atom Layer Deposition (ALD), Physical Vapor Deposition (PVD), Chemical Vapor Deposition (CVD) and Plasma Enhanced Chemical Vapor Deposition (PECVD) process, and preferably is ALD technology. In such a process, a smooth atom interface will be formed between the substrate 100 and the dielectric layer 110, and a gate dielectric layer with desired thickness can be formed. In the present invention, preferably the gate dielectric layer 110 has a thickness of about 10 Å to about 100 Å.

Then polycrystalline silicon or polycrystalline silicon doped with metal impurities is deposited on the surface of the gate dielectric layer 110. The metal impurities include at least one kind of metals (e.g. Ti, Ta, W, Mo, Pt etc.), as well as metal silicide, such as nickel silicide, titanium silicide or cobalt silicide. The method for forming the gate electrode 140 includes depositing the gate electrode materials to a thickness of 400 Å-2500 Å by employing ALD, CVD or PECVD technology.

A patterned mask is formed on the surface of the gate electrode materials by using the common-known photolithography, exposure and development processes, and then the gate electrode 140 is formed by etching the polycrystalline silicon employing the etching process.

In the following process steps, impurity ions 180 are implanted into the source region and the drain region to form the lightly doped regions 121 and 131 therein. The impurity ions 180 for a NMOS device are n-type impurity ions, for example, Phosphorus ions, Arsenic ions or Antimony ions. The n-type impurities implanted into the substrate generate relatively strong pressure stress in the lightly doped regions 121 and 131, and when the source/drain metal silicide contact layer is formed in follow-up processes, since in the technology beyond 65 nm, metal Ni is mainly adopted as the metal in the metal silicide, and it has a relatively large diffusion coefficient in Si-contained materials and apt to diffuse into the lightly doped regions 121 and 131 under the action of the pressure stress in the lightly doped regions 121 and 131 to form unexpected metal silicide. To prevent the metal Ni's diffusion to the lightly doped regions, according to an embodiment of the present invention, another kind of impurity ions, such as carbon ions (C⁺) is added to the implanted impurity ions 180. Combined action of the carbon ions and the n-type impurity ionic bonds can eliminate the pressure stress generated by the n-type impurity ions in the lightly doped regions 121 and 131. Therefore, during the process of forming the source/drain metal silicide contact layer, Ni atoms lose external forces under which the Ni atoms move towards the channel across the lightly doped regions 121 and 131. So, the phenomenon of forming the metal silicide in the lightly doped regions 121 and 131 is avoided.

In other embodiments of the present invention, fluorine ions (F⁺) or nitrogen ions (N⁺) can also be added to the implanted impurity ions 180 to eliminate the pressure stress generated by the n-type impurity ions in the lightly doped regions 121 and 131. In addition, the carbon ions (C⁺), fluorine ions (F⁺) or nitrogen ions (N⁺) can be implanted simultaneously when the n-type impurity ions are implanted, or be implanted prior or posterior to the implantation of the n-type impurity. In the present invention, the carbon ions (C⁺), fluorine ions (F⁺) or nitrogen ions (N⁺) are implanted at an implantation energy of about 1 KeV to about 6 KeV, and at a dosage of about 1E14 ions/cm² to about 1E15 ions/cm².

In the following, as shown in FIG. 5, offset spacer film material is deposited on the substrate 100 having the gate electrode 140 by employing PECVD in a reaction chamber, which is used for the follow-up ion implantation. The offset spacer film material can be Si₃N₄, SiNO or their combination. In this embodiment, silane and NH₃ are used to form the inter-sidewalls dividing wall material layer composed of Si₃N₄. Then the offset spacers 141 and 142 are formed by etching the inter-sidewalls dividing wall material layer.

In an embodiment of the present invention in which the self-aligned technology is employed, after the offset spacers 141 and 142 are respectively formed on each side of the gate electrode 140, as shown in FIG. 6, n-type impurity ions, such as phosphorus ions, arsenic ions or antimony ions, are implanted into the source/drain electrodes of the NMOS transistor to make the electrodes heavily doped with the n-type impurity ions, thus forming the source electrode 120 and the drain electrode 130 of the NMOS transistor. The lightly doped regions 121 and 131 locate below the offset spacers 141 and 142 respectively. The lightly doped region 121 acts as an extension portion of the source region 120 and the lightly doped region 131 acts as an extension portion of the drain region 130, and the channel length of the NMOS device is determined by the space therebetween.

In the following process steps, as shown in FIG. 7, metal Ni is deposited on the surfaces of the gate electrode 140, the source electrode 120 and the drain electrode 130. The deposition method is preferably a physical sputtering method, for example, Physical Vapor Deposition (PVD). Metal Ni deposited on the top of the gate electrode contacts directly with the polycrystalline silicon material, and metal Ni deposited on the surface of the source electrode 120 and the drain electrode 130 covers on the surface of the doped substrate. And then, thermal annealing, preferably, rapid thermal annealing, is conducted at a temperature of about 250° C. to about 350° C. During the annealing process, the metal Ni on the surface of the gate electrode 250 gradually diffuses towards the interior of the gate electrode 140, reacts with the silicon in the polycrystalline silicon gate electrode 140 and forms nickel silicide NiSi 153. The metal Ni deposited on the surfaces of the source electrode 120 and the drain electrode 130 penetrates towards the interiors of the source electrode 120 and the drain electrode 130 during the thermal annealing process, reacts with Si and forms metal silicide, i.e. NiSi 151 and 152.

Since before the offset spacers 141 and 142 are formed, carbon ions (C⁺), fluorine ions (F⁺) or nitrogen ions (N⁺) have been doped during the process of implanting the n-type impurity ions to form the lightly doped regions 121 and 131, and the reaction between the carbon ions (C⁺), fluorine ions (F⁺) or nitrogen ions (N⁺) and the n-type impurity ionic bonds can eliminate the pressure stress generated by the n-type impurity ions. Since Ni atoms deposited on the surface of the source region 120 and the drain region 130 lose external forces under which they move towards the channel across the lightly doped regions 121 and 131, the phenomenon of the metal Ni diffusing towards the channel will not occur. Thus the formation of the metal silicide in the lightly doped regions 121 and 131 adjacent to the channel is avoided and the generated leakage current is reduced.

FIG. 7 also shows a cross-section diagram showing the structure of an MOS device according to an embodiment of the present invention. As shown in FIG. 7, the MOS device in the embodiment of the present invention is a NMOS transistor, which includes a substrate 100, a gate dielectric layer 110 and a gate electrode 140, as well as offset spacers 141 and 142 formed on the surface of the substrate 100. A source region 120 and the drain region 130 are contained in the substrate. The source region 120 and a drain region 130 respectively have an extension portion extending below the offset spacers, i.e. lightly doped regions 121 and 131 formed prior to the source region 120 and the drain region 130. The source region 120, the drain region 130 and the gate electrode 140 have thereon metal silicide layers 151, 152 and 153 respectively, which are used for reducing contact resistances between contact holes of the upper connection structure and all the electrodes of the transistor.

In addition to the doped n-type impurity ions, carbon ions, fluorine ions or nitrogen ions are also included in the lightly doped regions 121 and 131. The ions are implanted at a dosage of about 1E14 ions/cm² to about 1E15 ions/cm². Thus the pressure stress generated by the n-type impurity ions in the substrate 100 can be eliminated and the diffusion of metal Ni towards the lightly doped regions 121 and 131 is prevented when the metal silicide layers 151, 152 and 153 are formed.

The forgoing description, for purpose of explanation, has been written with reference to specific embodiments. However, the illustrative discussions above are not intended to be exhaustive or to limit the invention to the precise forms disclosed. Those skilled in the art should understand that various changes may be made in form and detail without departing from the spirit and the scope of the present invention and therefore should be covered in the protection scope of the present invention defined by the appended claims and its equivalents.

1. A metal oxide semiconductor device, comprising:
a semiconductor substrate;
a gate electrode formed on a surface of the substrate and having an offset spacer on each side;
a source electrode and a drain electrode in the substrate, each of the source electrode and drain electrode having a lightly doped region;
metal silicide located on surfaces of the gate electrode, source electrode and drain electrode; wherein
the lightly doped regions include first impurity ions and second impurity ions.

2. The semiconductor device of claim 1, wherein, said first impurity is one of phosphorus, arsenic and antimony.

3. The semiconductor device of claim 1, wherein, said second impurity is one of carbon, nitrogen and fluorine.

4. The semiconductor device of claim 1, wherein, said substrate is a P-type substrate.

5. The semiconductor device of claim 1, wherein, said metal silicide is SiNi.

6. A method for manufacturing a metal oxide semiconductor device, comprising:
forming a gate electrode on a semiconductor substrate;
implanting first impurity ions and second impurity ions into parts of the substrate under each side of the gate electrode to form lightly doped regions;
depositing a dielectric layer and etching the dielectric layer to form offset spacers;
implanting the first impurity ions to form a source electrode and a drain electrode;
forming metal silicide on surfaces of the gate electrode, source electrode and drain electrode.

7. The method of claim 6, wherein, said substrate is a p-type substrate.

8. The method of claim 6, wherein, said first impurity is one of phosphorus, arsenic and antimony.

9. The method of claim 6, wherein, said second impurity is one of carbon, nitrogen or fluorine.

10. The method of claim 6, wherein, said metal silicide is SiNi.

11. The method of claim 6, further comprising implanting the second impurity ions at an implantation energy of about 1 KeV to about 6 KeV.

12. The method of claim 6, further comprising implanting the second impurity ions at a dosage of about 1E14 ions/cm² to about 1E15 ions/cm².
